(19) United States
(12) Patent Application Publication
(10) Pub. No.: US 2013/0100609 A1
(43) Pub. Date: Apr. 25, 2013

(54) CONTAINER DATA CENTER

(71) Applicants: HAI-LI WANG, Shenzhen City (CN); YONG-QIAN DENG, Shenzhen City (CN)

(72) Inventors: HAI-LI WANG, Shenzhen City (CN); YONG-QIAN DENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (TW)

(21) Appl. No.: 13/314,281

(22) Filed: Dec. 8, 2011

(30) Foreign Application Priority Data
Oct. 25, 2011 (CN) 201110327478.1

(51) Int. Cl. H05K 7/20; G05D 23/19; G01K 1/02

(52) U.S. Cl. 361/688; 165/11.1; 165/287

(57) ABSTRACT

A container data center includes a temperature control system to monitor a temperature of the container data center. The temperature control system includes a temperature sensor to sense the temperature of the container data center. The temperature control alarm system determines whether the sensed temperature is greater than first and second predetermined temperatures. The second predetermined temperature is greater than the first predetermined temperature. If the sensed temperature is greater than the first predetermined temperature, a cooling device is turned on to cool the container data center. If the sensed temperature is also greater than the second predetermined temperature, an alarm device is started and an alarm message is transmitted to a monitor center.

### TECHNICAL FIELD

The present disclosure relates to data centers, and particularly, to a container data center with a temperature control system.

### DESCRIPTION OF RELATED ART

With the development of container data centers, cooling problem of the container data center requires a great deal of attention. Temperature outside the container data center varies, thus the need of cooling the container data center also varies. Therefore, a temperature control system for the container data center is desirable.

### BRIEF DESCRIPTION OF THE DRAWINGS

Many aspects of the present embodiments can be better understood with reference to the following drawings. The components in the drawing are not necessarily drawn to scale, the emphasis instead being placed upon clearly illustrating the principles of the present disclosure. Moreover, in the drawings, all the views are schematic, and like reference numerals designate corresponding parts throughout the several views.

FIG. 1 is a block diagram of an exemplary embodiment of a container data center, wherein the container data center includes a main controller.

FIG. 2 is a block diagram of the main controller of FIG. 1.

FIGS. 3 and 4 are flowcharts of an exemplary embodiment of a temperature control method.

### DETAILED DESCRIPTION

The disclosure, including the accompanying drawings in which like references indicate similar elements, is illustrated by way of example and not by way of limitation. It should be noted that references to “an” or “one” embodiment in this disclosure are not necessarily to the same embodiment, and such references mean at least one.

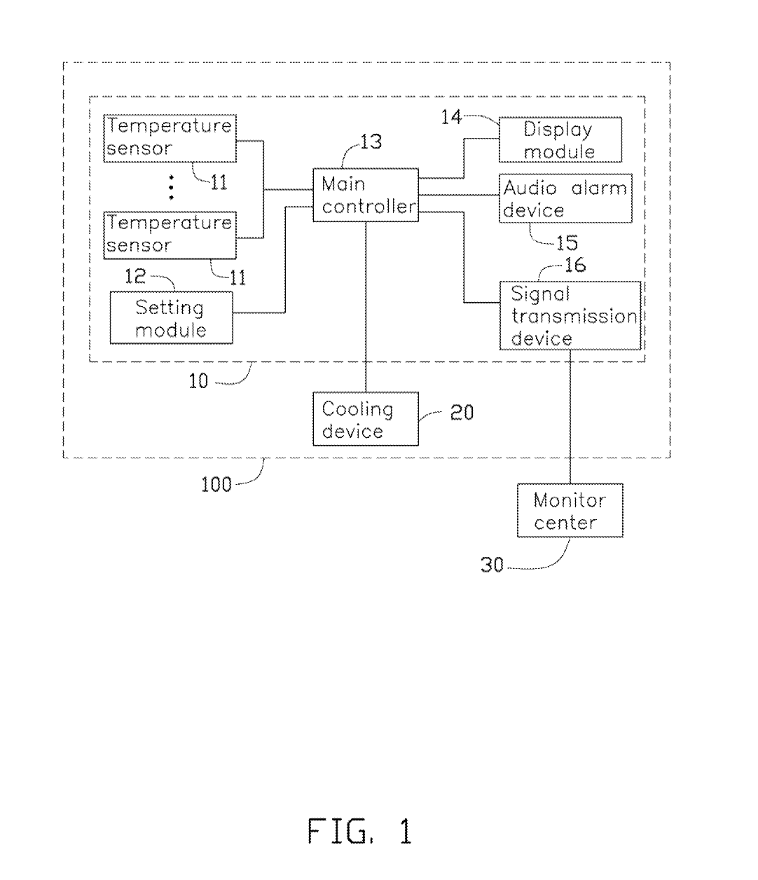

Referring to the FIG. 1, an embodiment of a container data center 100 includes a temperature control system 10 and a cooling device 20. The temperature control system 10 includes a plurality of temperature sensors 11, a setting module 12, a main controller 13, a display module 14, an audio alarm device 15, and a signal transmission device 16. The main controller 13 is connected to the temperature sensors 11, the setting module 12, the display module 14, the audio alarm device 15, and the signal transmission device 16.

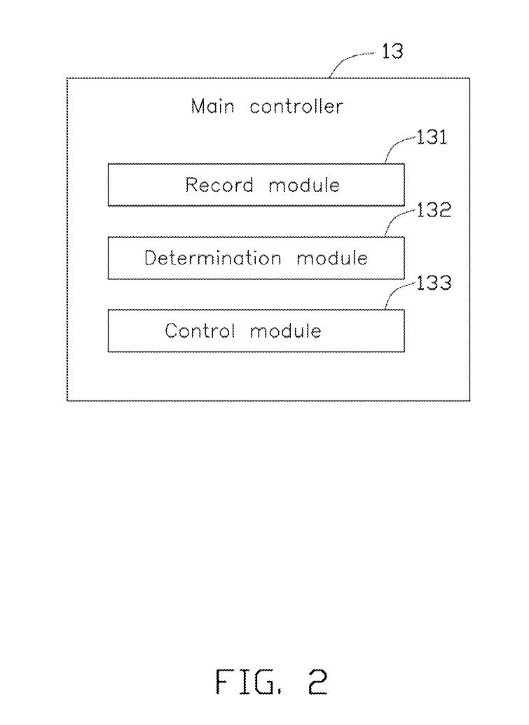

Referring to FIG. 2, the main controller 13 includes a record module 131, a determination module 132, and a control module 133.

The temperature sensors 11 are mounted on different positions of the container data center 100 to sense temperatures of the corresponding positions.

The record module 131 stores a first predetermined temperature and a second predetermined temperature. The second predetermined temperature is greater than the first predetermined temperature.

The setting module 12 can adjust the first and second predetermined temperatures stored in the record module 131. The record module 131 further stores the adjusted first and second predetermined temperatures.

The determination module 132 reads the sensed temperatures from the temperature sensors 11, and outputs the sensed temperatures to the display module 14. The determination module 132 further determines whether the sensed temperatures are greater than the first predetermined temperature. If at least one sensed temperature is greater than the first predetermined temperature, the determination module 132 determines whether the cooling device 20 is turned on. If the cooling device is turned on, the determination module 132 further determines whether the sensed temperatures are greater than the second predetermined temperature. If at least one sensed temperature is greater than the second predetermined temperature, the determination module 132 transmits an alarm signal to the control module 133. If none sensed temperature is greater than the second predetermined temperature, the determination module continues determines whether the sensed temperature is greater than the first predetermined temperature. If the cooling device 20 is not turned on, the determination module 132 transmits a turn-on signal to the control module 133. If none of the sensed temperature is greater than the first predetermined temperature, the determination module 132 transmits a turn-off signal to the control module 133.

The display module 14 displays the sensed temperatures.

The control module 133 turns on the cooling device 20 to cool the container data center 100 after receiving the turn-on signal, starts the audio alarm device 15 after receiving the alarm signal, and transmits an alarm message to a monitor center 30 through the signal transmission device 16 to indicate that the temperature of the container data center 100 is too high. The control module 133 further turns off the cooling device 20 to stop cooling the container data center 100 after receiving the turn-off signal.

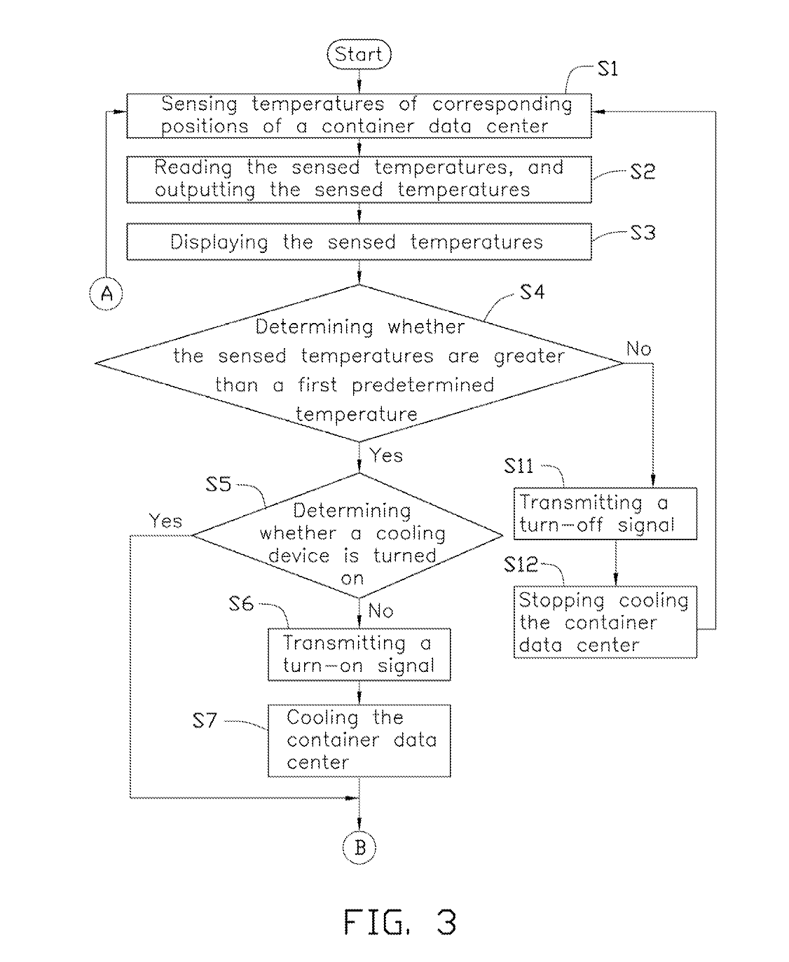

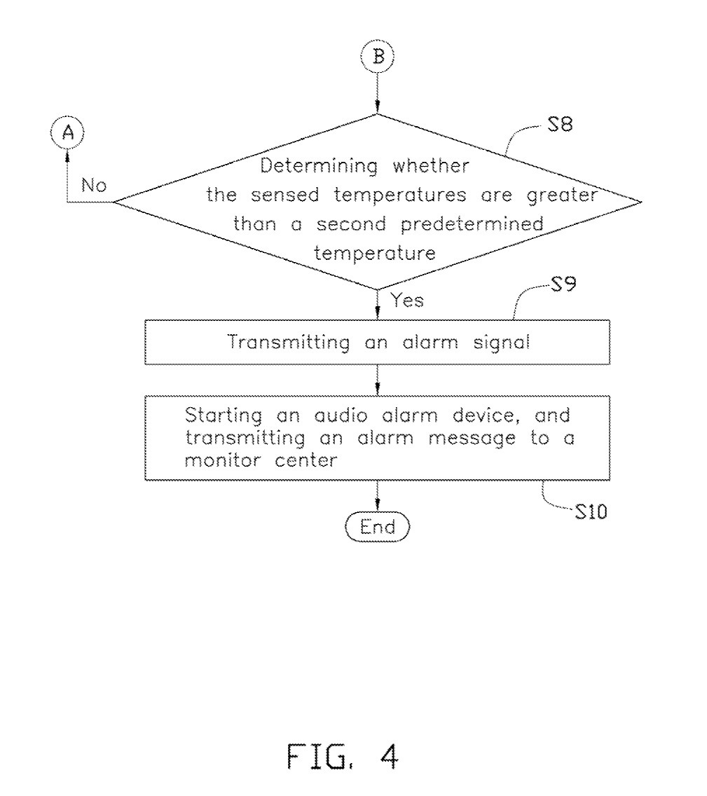

Referring to FIGS. 3 and 4, an exemplary embodiment of a temperature control method includes the following steps.

In step 1, the temperature sensors 42 sense the temperatures of the corresponding positions where the temperature sensors 42 are located in the container data center 100.

In step 2, the determination module 132 reads the sensed temperatures from the temperature sensors 11, and outputs the sensed temperatures to the display module 14.

In step 3, the display module 14 displays the sensed temperatures.

In step 4, the determination module 132 determines whether the sensed temperatures are greater than the first predetermined temperature. If at least one sensed temperature is greater than the first predetermined temperature, the procedure goes to step S5. If none of the sensed temperatures is greater than the first predetermined temperature, the procedure goes to step S11.

In step 5, the determination module 132 determines whether the cooling device 20 is turned on, if the cooling device 20 is turned on, the procedure goes to step S8. If the cooling device 20 is not turned on, the procedure goes to step S6.

In step 6, the determination module 132 transmits a turn-on signal to the control module 133.

In step 7, the control module 133 turns on the cooling device 20 to cool the container data center 100.

In step 8, the determination module 132 determines whether the sensed temperatures are greater than the second predetermined temperature. If at least one sensed temperature is greater than the second predetermined temperature, the procedure goes to step S9. If none of the sensed temperatures is greater than the second predetermined temperature, the procedure goes back to step S4.

In step 9, the determination module 132 transmits the alarm signal to the control module 133.

In step 10, the control module 133 turns on the audio alarm device 15, and transmits the alarm message to the monitor center 30 through the signal transmission device 16 to indicate that the temperature of the container data center 100 is too high.

In step 11, the determination module 132 transmits the turn-off signal to the control module 133.

In step 12, the control module 133 turns off the cooling device 20 to stop cooling the container data center 100, the procedure goes back to step S1.

Although numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. A container data center comprising:
a cooling device;
a temperature control system comprising:
a temperature sensor to sense a temperature;
an alarm device;
a signal transmission device;
a main controller connected to the temperature sensor, the alarm device, and the signal transmission device, the main controller comprising:
a record module storing a first predetermined temperature and a second predetermined temperature, wherein the second predetermined temperature is greater than the first predetermined temperature;
a determination module to read the sensed temperature from the temperature sensor, and determine whether the sensed temperature is greater than the first predetermined temperature, wherein if the sensed temperature is greater than the first predetermined temperature, the determination module determines whether the cooling device is turned on, if the cooling device is turned on, the determination module further determines whether the sensed temperature is greater than the second predetermined temperature, if the sensed temperature is greater than the second predetermined temperature, the determination module outputs an alarm signal, if the cooling device is not turned on, the determination module outputs a turn-on signal, if the sensed temperature is not greater than the first predetermined temperature, the determination module outputs a turn-off signal; and
a control module to turn on the cooling device after receiving the turn-on signal, start the alarm device after receiving the alarm signal, transmit an alarm message to a monitor center through the signal transmission device, and turn off the cooling device after receiving the turn-off signal.

2. The container data center of claim 1, wherein the temperature control system further comprises a setting module connected to the main controller, the setting module adjusts the first and second predetermined temperatures, the record module stores the adjusted first and second predetermined temperatures.

3. The container data center of claim 1, wherein the temperature control system further comprises a display module connected to the main controller, the display module displays the sensed temperature, the determination module outputs the sensed temperature to the display module after reading the sensed temperature.

4. A temperature control system to monitor a temperature of a container data center, the temperature control system comprising:
a temperature sensor to sense the temperature of the container data center;
an alarm device;
a signal transmission device;
a main controller connected to the temperature sensor, the alarm device, and the signal transmission device, the main controller comprising:
a record module storing a first predetermined temperature and a second predetermined temperature, wherein the second predetermined temperature is greater than the first predetermined temperature;
a determination module to read the sensed temperature from the temperature sensor, and determine whether the sensed temperature is greater than the first predetermined temperature, wherein if the sensed temperature is greater than the first predetermined temperature, the determination module determines whether the cooling device is turned on, if the cooling device is turned on, the determination module further determines whether the sensed temperature is greater than the second predetermined temperature, if the sensed temperature is greater than the second predetermined temperature, the determination module outputs an alarm signal, if the cooling device is not turned on, the determination module outputs a turn-on signal, if the sensed temperature is greater than the second predetermined temperature, the determination module outputs an alarm signal, if the sensed temperature is not greater than the first predetermined temperature, the determination module outputs a turn-off signal; and
a control module to turn on the cooling device after receiving the turn-on signal to cool the container data center, start the alarm device after receiving the alarm signal, transmit an alarm message to a monitor center through the signal transmission device, and turn off the cooling device to stop cooling the container data center after receiving the turn-off signal.

5. The temperature control system of claim 4, further comprising a setting module connected to the main controller, wherein the setting module adjusts the first and second predetermined temperatures, the record module stores the adjusted first and second predetermined temperatures.

6. The temperature control system of claim 4, further comprising a display module connected to the main controller, wherein the display module displays the sensed temperature, the determination module outputs the sensed temperature to the display module after reading the sensed temperature.

7. A temperature control method to monitor a temperature of a container data center, the temperature control method comprising:
sensing a temperature of the container data center;
reading the sensed temperature;
determining whether the sensed temperature is greater than a first predetermined temperature;
determining whether a cooling device being turned on if the sensed temperature is greater than the first predetermined temperature;
transmitting a turn-on signal if the cooling device being not turned on;
cooling the container data center after receiving the turn-on signal;
determining whether the sensed temperature is greater than a second predetermined temperature if the cooling device being turned on, wherein if the sensed temperature is not greater than the second predetermined temperature, the procedure goes back to the step of determining whether the sensed temperature is greater than a first predetermined temperature;
transmitting an alarm signal if the sensed temperature is greater than the second predetermined temperature;
starting an alarm device, and transmitting an alarm message to a monitor center;
transmitting a turn-off signal if the sensed temperature is not greater than the first predetermined temperature; and
stopping cooling the container data center.

8. The temperature control method of claim 7, further comprising a step of displaying the sensed temperature between the step of reading the sensed temperature and the step of determining whether the sensed temperature is greater than a first predetermined temperature.
